(19) United States
(12) Patent Application Publication
(10) Pub. No.: US 2026/0107662 A1
(43) Pub. Date: Apr. 16, 2026

(54) DISPLAY DEVICE AND ELECTRONIC DEVICE INCLUDING THE SAME

(71) Applicant: Samsung Display Co., Ltd., Yongin-si (KR)

(72) Inventors: Hee Sung LIM, Yongin-si (KR); Young Moo KWON, Yongin-si (KR); Young Kwan KIM, Yongin-si (KR); Young Dae SONG, Yongin-si (KR); Hyo Seok YANG, Yongin-si (KR)

(21) Appl. No.: 19/209,678

(22) Filed: May 15, 2025

(30) Foreign Application Priority Data
Oct. 11, 2024 (KR) 10-2024-0138406

(51) Int. Cl. H10K 59/80; H10H 29/30

(52) U.S. Cl. CPC H10K 59/8722; H10H 29/30

(57) ABSTRACT

A display device includes: a cover window; a display panel on the cover window; a panel bottom member on the display panel; and an adhesive unit on at least one of the cover window or the panel bottom member. The adhesive unit includes a plurality of adhesive members spaced from one another in a direction to have spaces between the adhesive members.

### CROSS-REFERENCE TO RELATED APPLICATION

The present application claims priority to and the benefit of Korean Patent Application No. 10-2024-0138406, filed on Oct. 11, 2024, in the Korean Intellectual Property Office, the entire disclosure of which is incorporated by reference herein.

### BACKGROUND

### 1. Field

Aspects of embodiments of the present disclosure relate to a display device, and an electronic device including the display device.

### 2. Description of the Related Art

Electronic devices, such as a smart phone, a tablet PC, a digital camera, a laptop computer, a navigation device, and a smart TV, may include an organic light-emitting display device for displaying images.

Organic light-emitting display devices may have good luminance, low driving voltage, fast response speeds, and a wide range of color reproduction, and accordingly, are being employed by a variety of devices including smart phones. An organic light-emitting display device includes a display panel including organic light-emitting elements. In an organic light-emitting element, a cathode electrode and an anode electrode are disposed around an organic emissive layer. When a voltage is applied to the cathode electrode and the anode electrode, visible light is generated in the organic emissive layer connected to the two electrodes.

A back cover may be disposed on the rear surface of an organic light-emitting display device to protect the rear surface of the organic light-emitting display device. The organic light-emitting display device and the back cover may be coupled with each other by a separate adhesive unit.

The above information disclosed in this Background section is for enhancement of understanding of the background of the present disclosure, and therefore, it may contain information that does not constitute prior art.

### SUMMARY

Embodiments of the present disclosure may be directed to a display device capable of preventing or substantially preventing a deformation of an adhesive unit that couples the display device with an electronic device, and an electronic device including the display device.

However, the aspects and features of the present disclosure are not restricted to those set forth herein. The above and other aspects and features of the present disclosure will become more apparent to those having ordinary skill in the art by referencing the detailed description of the present disclosure below.

According to one or more embodiments of the present disclosure, a display device includes: a cover window; a display panel on the cover window; a panel bottom member on the display panel; and an adhesive unit on at least one of the cover window or the panel bottom member. The adhesive unit includes a plurality of adhesive members spaced from one another in a direction to have spaces between the adhesive members.

In an embodiment, lengths of the adhesive members in the direction may become shorter along the direction.

In an embodiment, lengths of the spaces in the direction may become shorter along the direction.

In an embodiment, the adhesive unit may further include: a first cover covering a surface of the adhesive members; and a second cover covering an opposite surface of the adhesive members. The first cover may be configured to be separated from the adhesive members before the adhesive unit is disposed on at least one of the cover window or the panel bottom member.

In an embodiment, an area of the first cover may be larger than an area of the second cover in a plan view.

In an embodiment, the adhesive members may include: a plurality of first adhesive members on at least one of the cover window or the panel bottom member; and a plurality of second adhesive members on the first adhesive members.

In an embodiment, lengths of the first and second adhesive members in the direction may become shorter along the direction.

In an embodiment, a thickness of the first adhesive members may be smaller than a thickness of the second adhesive members.

In an embodiment, the display device may further include: a connecting member connected to the display panel; and a driver circuit board connected to the connecting member. The driver circuit board may overlap with a portion of the panel bottom member when the connecting member is bent, and the adhesive unit may be located on a portion of the panel bottom member where the driver circuit board and the panel bottom member do not overlap with each other.

In an embodiment, the adhesive unit may be located on the cover window in an area where the cover window and the panel bottom member do not overlap with each other, and in an area where the cover window and the connecting member do not overlap with each other.

According to one or more embodiments of the present disclosure, an electronic device includes: a cover window; a display panel on the cover window; a panel bottom member on the display panel; a bracket supporting the cover window and the panel bottom member; and a plurality of adhesive units between the cover window and the bracket, and between the panel bottom member and the bracket. Each of the adhesive units includes a plurality of adhesive members, and the adhesive members are spaced from one another in a direction to have spaces between the adhesive members.

In an embodiment, lengths of the adhesive members in the direction may become shorter along the direction.

In an embodiment, lengths of the spaces in the direction may become shorter along the direction.

In an embodiment, each of the adhesive units may further include: a first cover covering a surface of the adhesive members; and a second cover covering an opposite surface of the adhesive members. The first cover of a corresponding adhesive unit of the adhesive units may be configured to be separated from the adhesive members before the corresponding adhesive unit comes into contact with the cover window or the panel bottom member, and the second cover of the corresponding adhesive unit may be configured to be separated from the adhesive members before the corresponding adhesive unit comes into contact with the bracket.

In an embodiment, an area of the first cover may be larger than an area of the second cover in a plan view.

In an embodiment, the adhesive members may include: a plurality of first adhesive members on the cover window or the panel bottom member; and a plurality of second adhesive members on the bracket. The first adhesive members and the second adhesive members may overlap with each other.

In an embodiment, lengths of the first and second adhesive members in the direction may become shorter along the direction.

In an embodiment, a thickness of the first adhesive members may be smaller than a thickness of the second adhesive members.

In an embodiment, the electronic device may further include: a connecting member connected to the display panel; and a driver circuit board connected to the connecting member. The driver circuit board may overlap with a portion of the panel bottom member when the connecting member is bent, and at least one of the adhesive units may be located on a portion of the panel bottom member where the driver circuit board and the panel bottom member do not overlap with each other.

In an embodiment, at least some of the adhesive units may be located on the cover window in an area where the cover window and the panel bottom member do not overlap each other, and in an area where the cover window and the connecting member do not overlap with each other.

According to some embodiments of the present disclosure, by dividing an adhesive unit that couples a display device with an electronic device into a plurality of pieces, it may be possible to prevent or substantially prevent a deformation of the adhesive unit during a process of attaching the adhesive unit to the display device, and the adhesive unit may be attached to a desired position (e.g., a correct position) of the display device.

However, the present disclosure is not limited to the above aspects and features, and the above and additional aspects and features will be set forth, in part, in the detailed description that follows with reference to the drawings, and in part, may be apparent therefrom, or may be learned by practicing one or more of the presented embodiments of the present disclosure.

### BRIEF DESCRIPTION OF THE DRAWINGS

The above and other aspects and features of the present disclosure will be more clearly understood from the following detailed description of the illustrative, non-limiting embodiments with reference to the accompanying drawings.

FIG. 1 is a plan view of an electronic device according to an embodiment of the present disclosure.

FIG. 2 is a plan view illustrating a connecting member of a display device that is bent according to an embodiment of the present disclosure.

FIG. 3 is a bottom view illustrating a connecting member of a display device that is unfolded according to an embodiment of the present disclosure.

FIG. 4 is a side view illustrating a part of a display device according to an embodiment of the present disclosure.

FIG. 5 is a cross-sectional view illustrating a display panel of FIG. 3.

FIG. 6 is a plan view of an adhesive unit of FIG. 3.

FIG. 7 is a cross-sectional view taken along the line A - A′ of FIG. 6.

FIG. 8 is a cross-sectional view taken along the line B - B′ of FIG. 6.

FIG. 9 is a view illustrating an adhesive unit of FIG. 3 disposed on a cover window or a panel bottom member.

FIG. 10 is a view illustrating a first cover that is removed from an adhesive unit, and the adhesive unit is moved so that one side comes into contact with a cover window or a panel bottom member.

FIG. 11 is a view illustrating a process of an adhesive roller that is moved while pressing the adhesive unit shown in FIG. 10.

FIG. 12 is a view illustrating an adhesive unit that is attached to a cover window or a panel bottom member via the process shown in FIG. 11.

FIG. 13 is a cross-sectional view illustrating an electronic device coupled with a display device according to an embodiment of the present disclosure.

### DETAILED DESCRIPTION

Hereinafter, embodiments will be described in more detail with reference to the accompanying drawings, in which like reference numbers refer to like elements throughout. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described. Unless otherwise noted, like reference numerals denote like elements throughout the attached drawings and the written description, and thus, redundant description thereof may not be repeated.

When a certain embodiment may be implemented differently, a specific process order may be different from the described order. For example, two consecutively described processes may be performed at the same or substantially at the same time, or may be performed in an order opposite to the described order.

Further, as would be understood by a person having ordinary skill in the art, in view of the present disclosure in its entirety, each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner, unless otherwise stated or implied.

In the drawings, the relative sizes, thicknesses, and ratios of elements, layers, and regions may be exaggerated and/or simplified for clarity. Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

Further, it should be expected that the shapes shown in the figures may vary in practice depending, for example, on tolerances and/or manufacturing techniques. Accordingly, the embodiments of the present disclosure should not be construed as being limited to the specific shapes shown in the figures, and should be construed considering changes in shapes that may occur, for example, as a result of manufacturing. As such, the shapes shown in the drawings may not depict the actual shapes of areas of the device, and the present disclosure is not limited thereto.

In the figures, the x-axis, the y-axis, and the z-axis are not limited to three axes of the rectangular coordinate system, and may be interpreted in a broader sense. For example, the x-axis, the y-axis, and the z-axis may be perpendicular to or substantially perpendicular to one another, or may represent different directions from each other that are not perpendicular to one another.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

It will be understood that when an element or layer is referred to as being “on,” “connected to,” or “coupled to” another element or layer, it can be directly on, connected to, or coupled to the other element or layer, or one or more intervening elements or layers may be present. Similarly, when a layer, an area, or an element is referred to as being “electrically connected” to another layer, area, or element, it may be directly electrically connected to the other layer, area, or element, and/or may be indirectly electrically connected with one or more intervening layers, areas, or elements therebetween. In addition, it will also be understood that when an element or layer is referred to as being “between” two elements or layers, it can be the only element or layer between the two elements or layers, or one or more intervening elements or layers may also be present.

The terminology used herein is for the purpose of describing particular embodiments and is not intended to be limiting of the present disclosure. As used herein, the singular forms “a” and “an” are intended to include the plural forms as well, unless the context clearly indicates otherwise. It will be further understood that the terms “comprises,” “comprising,” “includes,” “including,” “has,” “have,” and “having,” when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. For example, the expression “A and/or B” denotes A, B, or A and B. Expressions such as “at least one of,” when preceding a list of elements, modify the entire list of elements and do not modify the individual elements of the list. For example, the expression “at least one of a, b, or c,” “at least one of a, b, and c,” and “at least one selected from the group consisting of a, b, and c” indicates only a, only b, only c, both a and b, both a and c, both b and c, all of a, b, and c, or variations thereof.

As used herein, the term “substantially,” “about,” and similar terms are used as terms of approximation and not as terms of degree, and are intended to account for the inherent variations in measured or calculated values that would be recognized by those of ordinary skill in the art. Further, the use of “may” when describing embodiments of the present disclosure refers to “one or more embodiments of the present disclosure.” As used herein, the terms “use,” “using,” and “used” may be considered synonymous with the terms “utilize,” “utilizing,” and “utilized,”respectively.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

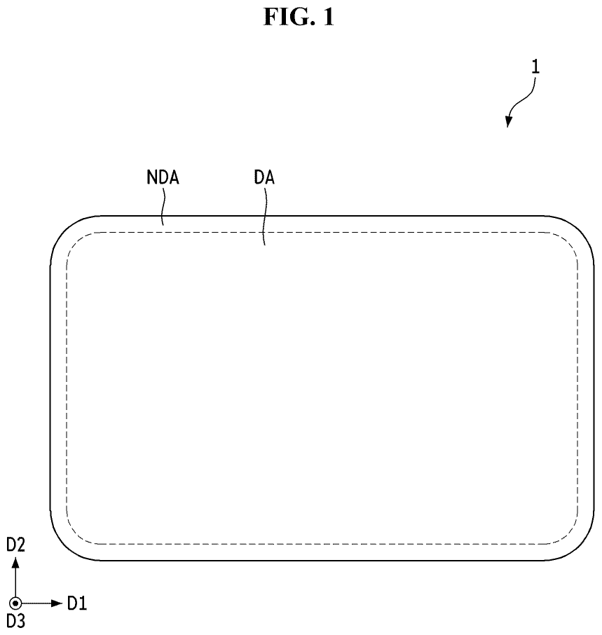

FIG. 1 is a plan view of an electronic device according to an embodiment of the present disclosure.

Referring to FIG. 1, the electronic device 1 according to an embodiment of the present disclosure may include a variety of suitable electronic devices that provide a display screen. Examples of the electronic device 1 may include, but are not limited to, a mobile phone, a smart phone, a tablet PC, a mobile communications terminal, an electronic organizer, an e-book, a personal digital assistant (PDA), a portable multimedia player (PMP), a navigation device, an ultra mobile PC (UMPC), a television set, a game machine, a wristwatch-kind of electronic device, a head-mounted display, a personal computer monitor, a laptop computer, a vehicle instrument cluster, a digital camera, a camcorder, an outdoor billboard, an electronic billboard, various medical apparatuses, various inspection devices, various home appliances including a display area, such as a refrigerator and a laundry machine, Internet of things (IoT) devices, and the like. Examples of the electronic device 1 may include, but are not limited to, a smartphone, a tablet PC, a laptop computer, and the like.

The electronic device 1 may include a display area DA and a non-display area NDA. The shape of the display area DA may follow the shape of the electronic device 1 when viewed from the top (e.g., in a plan view). For example, when the electronic device 1 has a rectangular shape when viewed from the top (e.g., in a plan view), the display area DA may also have a rectangular shape when viewed from the top.

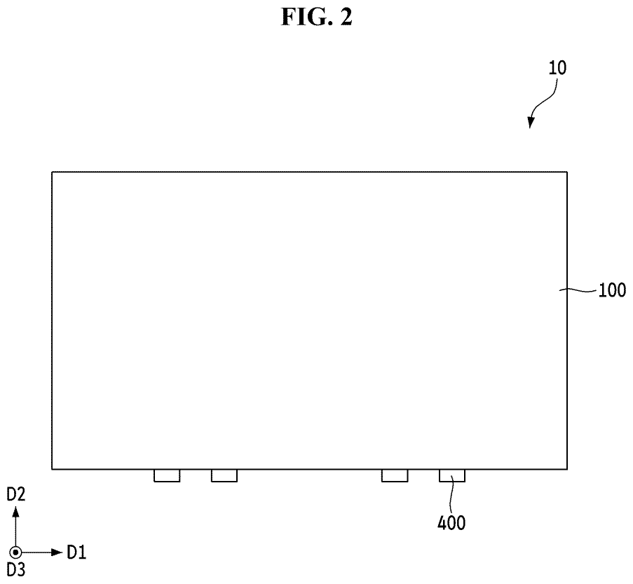

The display area DA may include a plurality of pixels of a display device 10 (e.g., see FIG. 2) to display images. The non-display area NDA may display no images, because it does not include the pixels of the display device 10. The non-display area NDA may be disposed around the display area DA. The non-display area NDA may surround (e.g., around a periphery of) the display area DA, but the present disclosure is not limited thereto. The display area DA may be partially surrounded (e.g., around a periphery thereof) by the non-display area NDA.

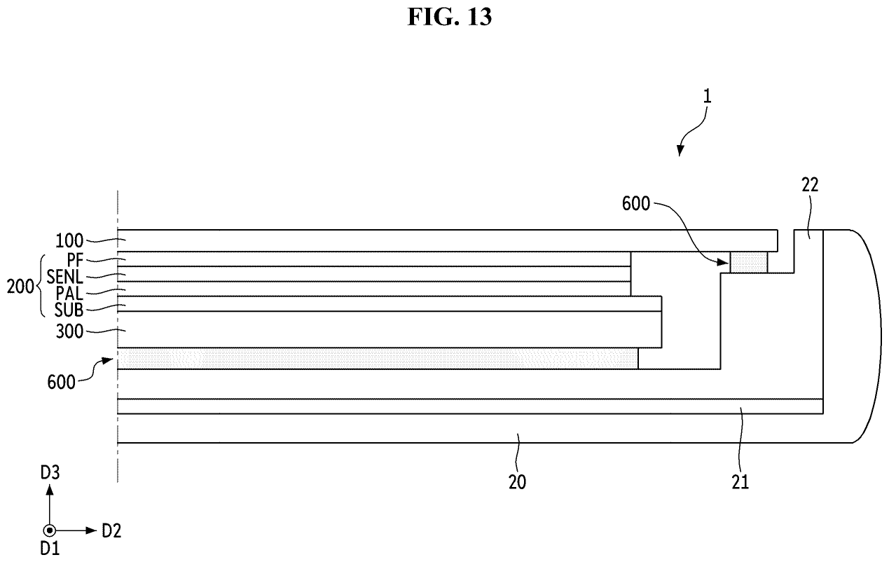

As will be described in more detail below, the electronic device 1 according to an embodiment of the present disclosure may include the display device 10, a back cover 20, a vapor chamber 21, and a bracket 22 (e.g., see FIG. 13).

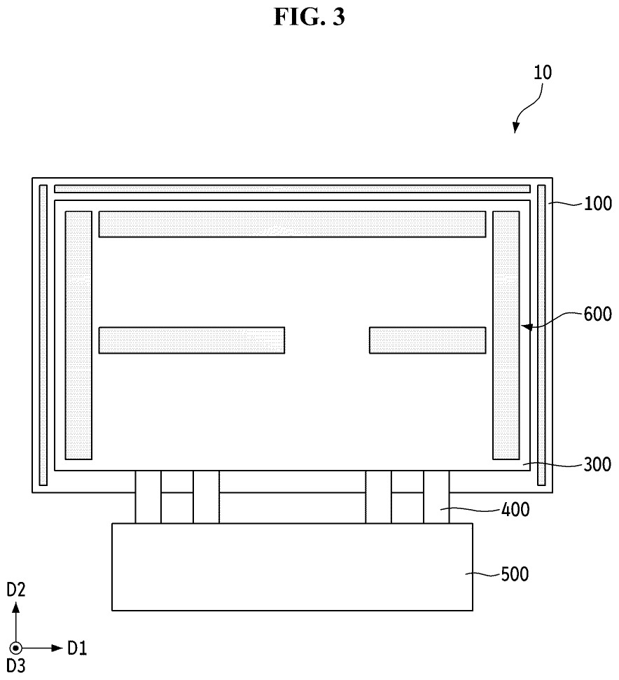

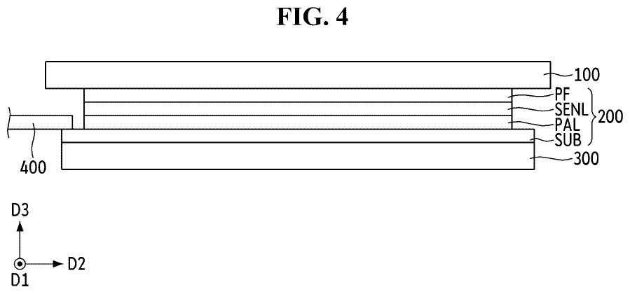

FIG. 2 is a plan view illustrating a connecting member of a display device that is bent according to an embodiment of the present disclosure. FIG. 3 is a bottom view illustrating the connecting member of the display device that is unfolded according to an embodiment of the present disclosure. FIG. 4 is a side view illustrating a part of the display device according to an embodiment of the present disclosure.

As used herein, the display device 10 may be a device for displaying moving images and/or still images. The display device 1 may be used as the display screen of various suitable portable electronic devices, such as a mobile phone, a smart phone, a tablet PC, a smart watch, a watch phone, a mobile communications terminal, an electronic notebook, an electronic book, a portable multimedia player (PMP), a navigation device, and a ultra mobile PC (UMPC), as well as the display screen of various suitable products, such as a television, a notebook, a monitor, a billboard, and an Internet of Things (IoT) device. As another example, the display device 10 may be used as a display screen applied to the center fascia of a vehicle.

The display device 10 may be a light-emitting display device, such as an organic light-emitting display device that uses organic light-emitting diodes, a quantum-dot light-emitting display device including a quantum-dot light-emitting layer, an inorganic light-emitting display device including an inorganic semiconductor, and a micro light-emitting display device that uses micro light-emitting diodes (LED). Hereinafter, for convenience of illustration, an organic light-emitting display device may be described in more detail as an example of the display device 10. However, the present disclosure is not limited thereto.

The first direction D1 may refer to a direction parallel to or substantially parallel to a side of the display device 1, for example, such as the horizontal direction of the display device 10 when viewed from the top (e.g., in a plan view). A second direction D2 may refer to a direction parallel to or substantially parallel to another side of the display device 10 that meets the side of the display device 10, for example, such as the vertical direction of the display device 10 when viewed from the top (e.g., in a plan view). A third direction D3 may refer to the thickness direction of the display device 10.

The display device 10 may have a quadrangular shape, such as a rectangular shape when viewed from the top (e.g., in a plan view). For example, the display device 10 may have a rectangular shape having longer sides extending in the first direction D1, and shorter sides extending in the second direction D2 when viewed from the top (e.g., in a plan view). The corners where the longer sides extending in the first direction D1 meet the shorter sides extending in the second direction D2 may be rounded with a suitable curvature (e.g., a predetermined curvature), or may be right angled. The shape of the display device 10 when viewed from the top (e.g., in a plan view) is not limited to a rectangular shape, but may be formed in another polygonal shape, a circular shape, or an elliptical shape.

Referring to FIGS. 2 to 4, the display device 10 according to an embodiment of the present disclosure may include a cover window 100, a display panel 200, a panel bottom member 300, a connecting member 400, a driver circuit board 500, and an adhesive unit (e.g., an adhesive stack) 600.

The cover window 100 may include a suitable material having a high light transmittance. The cover window 100 may include a polymer resin such as polyimide, or glass. The cover window 100 may be attached onto a polarizing film PF of the display panel 200 by an adhesive member, such as an optically clear adhesive (OCA) film.

The display panel 200 may be disposed under the cover window 100. The display panel 200 may have a rectangular shape having longer sides extending in the first direction D1, and shorter sides extending in the second direction D2 when viewed from the top (e.g., in a plan view). In the display panel 200, the corners where the longer sides extending in the first direction D1 meet the shorter sides extending in the second direction D2 may be formed at a right angle, or may be rounded with a suitable curvature (e.g., a predetermined curvature). The display panel 200 may have a quadrangular shape other than a rectangle, a polygonal shape other than a quadrangular shape, a circular shape, an oval shape, or an irregular shape when viewed from the top (e.g., in a plan view).

The display panel 200 may include a display area where a plurality of emission areas that emits light is arranged, and a non-display area disposed around the display area. The non-display area may surround (e.g., around a periphery of) the display area. A plurality of display pads may be disposed in the non-display area at one edge of the display panel 200.

The display panel 200 may include a substrate SUB, a display unit (e.g., a display layer) PAL, a sensor unit (e.g., a sensor layer) SENL, and a polarizing film PF.

The substrate SUB may be made of an insulating material, such as glass, quartz, and/or a polymer resin. The substrate SUB may be a rigid substrate, or a flexible substrate that may be bent, folded, rolled, and the like.

The display unit PAL may be disposed on the substrate SUB. The display unit PAL may be a layer including a plurality of emission areas that emit light. The display unit PAL may include a buffer film, a thin-film transistor layer at (e.g., in or on) which thin-film transistors are disposed, a light-emitting element layer that emits light, and an encapsulating layer for encapsulating the light-emitting element layer.

The sensor unit SENL may be disposed on the display unit PAL. The sensor unit SENL may include sensor electrodes, and may sense whether or not there is a user's touch.

The polarizing film PF may be disposed on the sensor unit SENL. The polarizing film PF may prevent or substantially prevent the deterioration of image visibility of the display panel 200 due to a reflection of external light. The polarizing film may include a linear polarizer, and a retardation film such as a λ/4 (quarter-wave) plate. The phase retardation film may be disposed on the sensor unit SENL, and the linear polarizer may be disposed on the phase retardation film. The cover window 100 may be disposed on the polarizing film PF.

The panel bottom member 300 may be disposed under the substrate SUB. The panel bottom member 300 may be attached to the lower surface of the substrate SUB by an adhesive layer. The adhesive layer may be a pressure-sensitive adhesive (PSA). The panel bottom member 300 may include at least one of a light-absorbing member for absorbing light incident from the outside, a buffer member for absorbing an external impact, or a heat dissipating member for efficiently discharging heat from the display panel 200.

The light-absorbing member may be disposed under the substrate SUB. The light-absorbing member blocks the transmission of light to prevent or substantially prevent the elements disposed thereunder, such as the driver circuit board 500, from being seen from above the display panel 200. The light-absorbing member may include a light-absorbing material, such as a black pigment and a black dye.

The buffer member may be disposed under the light-absorbing member. The buffer member absorbs an external impact to prevent or substantially prevent the display panel 200 from being damaged. The buffer member may be made up of a single layer or multiple layers. For example, the buffer member may be formed of a polymer resin, such as polyurethane, polycarbonate, polypropylene, and/or polyethylene, or may be formed of a suitable material having an elasticity, such as a rubber and/or a sponge obtained by foaming a urethane-based material or an acrylic-based material.

The heat dissipating member may be disposed under the buffer member. The heat dissipation member may include a first heat dissipation layer including graphite or carbon nanotubes, and a second heat dissipation layer formed of a thin metal film, such as copper, nickel, ferrite, and/or silver, which may block electromagnetic waves and may have a high thermal conductivity.

The connecting member 400 may be connected to a plurality of display pads of the display panel 200 through a conductive adhesive member, such as an anisotropic conductive film. Accordingly, the display panel 200 and the connecting member 400 may be electrically connected with each other.

In addition, the connecting member 400 may be connected to a plurality of circuit pads of the driver circuit board 500 through a conductive adhesive member, such as an anisotropic conductive film. As a result, the connecting member 400 and the driver circuit board 500 may be electrically connected with each other.

The connecting member 400 may be a flexible printed circuit board or a chip-on film.

The driver circuit board 500 may overlap with the panel bottom member 300 when the connecting member 400 is bent. The driver circuit board 500 may be a flexible printed circuit board (FPCB) that may be bent, a rigid printed circuit board (PCB) that may not be easily bent, or a composite printed circuit board including both a rigid printed circuit board and a flexible printed circuit board.

The driver circuit board 500 may process a signal converted by a control circuit board to transmit it to the display panel 200. The driver circuit board 500 may be electrically connected to the display panel 200 by the connecting member 400.

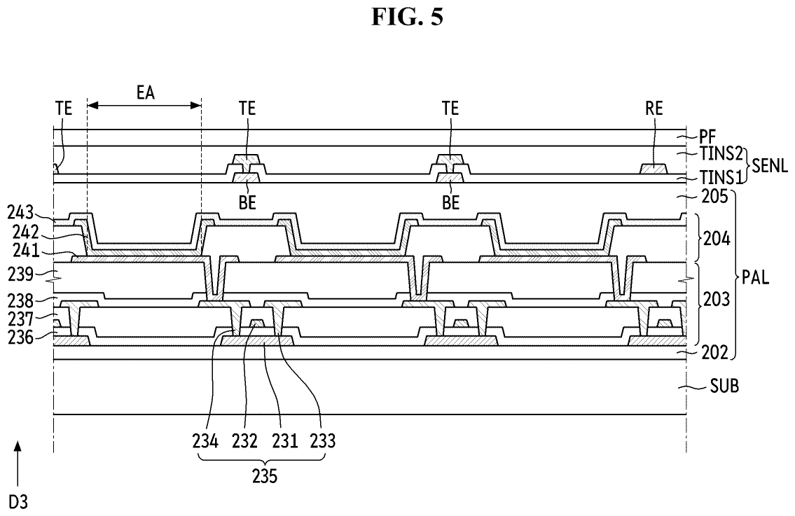

FIG. 5 is a cross-sectional view illustrating the display panel of FIG. 3.

Referring to FIG. 5, the display unit PAL may include a buffer layer 202, a thin-film transistor layer 203, a light-emitting element layer 204, and an encapsulation layer 205.

The buffer layer 202 may be formed on the substrate SUB. The buffer layer 202 may be formed on the substrate SUB to protect thin-film transistors 235 and light-emitting elements from moisture permeating through the substrate SUB that may be susceptible to moisture permeation. The buffer layer 202 may be formed of a plurality of inorganic layers that are stacked on one another alternately. For example, the buffer layer 202 may be made up of multiple layers in which one or more inorganic layers of a silicon oxide layer (SiOx), a silicon nitride layer (SiNx), and/or SiON are stacked on one another alternately. However, the present disclosure is not limited thereto, and the buffer layer 202 may be omitted as needed or desired.

The thin-film transistor layer 203 is formed on the buffer layer 202. The thin-film transistor layer 203 includes the thin-film transistors 235, a gate insulator 236, an interlayer dielectric film 237, a protective film 238, and an organic film 239.

Each of the thin-film transistors 235 includes an active layer 231, a gate electrode 232, a source electrode 233, and a drain electrode 234. In FIG. 5, the thin-film transistors 235 are illustrated as being implemented as top-gate transistors in which the gate electrode 232 is located above the active layer 231. However, the present disclosure is not limited thereto. In other words, the thin-film transistors 235 may be implemented as bottom-gate transistors in which the gate electrode 232 is located below (e.g., underneath) the active layer 231, or as double-gate transistors in which the gate electrodes 232 are disposed above and below (e.g., underneath) the active layer 231.

The active layer 231 is formed on the buffer layer 202. The active layer 231 may be formed of a silicon-based semiconductor material or an oxide-based semiconductor material. For example, the active layer 231 may be formed of polycrystalline silicon, amorphous silicon, or an oxide semiconductor. A light-blocking layer for blocking external light incident on the active layer 231 may be formed between the buffer layer 202 and the active layer 231.

The gate insulator 236 may be formed on the active layer 231. The gate insulator 236 may be formed of an inorganic layer, for example, such as a silicon oxide layer (SiOx), a silicon nitride layer (SiNx), or multilayers thereof.

The gate electrodes 232 may be formed on the gate insulating layer 236. The gate electrodes 232 and gate lines may be made up of a single layer or multiple layers of one or more of molybdenum (Mo), aluminum (Al), chromium (Cr), gold (Au), titanium (Ti), nickel (Ni), neodymium (Nd), copper (Cu), or a suitable alloy thereof.

The interlayer dielectric film 237 may be formed over the gate electrodes 232 and the gate lines. The interlayer dielectric film 237 may be formed of an inorganic layer, for example, such as a silicon oxide layer (SiOx), a silicon nitride layer (SiNx), or multilayers thereof.

The source electrodes 233 and the drain electrodes 234 may be formed on the interlayer dielectric film 237. Each of the source electrodes 233 and the drain electrodes 234 may be connected to a corresponding active layer 231 through a corresponding contact hole penetrating through the gate insulating layer 236 and the interlayer dielectric layer 237. The source electrode 233 and the drain electrode 234 may be made up of a single layer or multiple layers of one or more of molybdenum (Mo), aluminum (Al), chromium (Cr), gold (Au), titanium (Ti), nickel (Ni), neodymium (Nd), copper (Cu) or a suitable alloy thereof.

The protective film 238 may be formed on the source electrode 233 and the drain electrode 234 in order to insulate the thin-film transistors 235. The protective layer 238 may be formed of an inorganic layer, for example, such as a silicon oxide layer (SiOx), a silicon nitride layer (SiNx), or multilayers thereof.

The organic film 238 may be formed on the protective film 235 to provide a flat or substantially flat surface over the thin-film transistors 335 having difference levels. The organic film 239 may be implemented as an organic layer, such as an acryl resin, an epoxy resin, a phenolic resin, a polyamide resin, and/or a polyimide resin.

The light-emitting element layer 204 is formed on the thin-film transistor layer 203. The light-emitting element layer 204 includes the light-emitting elements and a bank.

The light-emitting elements and the bank are formed on the organic film 239. An organic light-emitting device including an anode electrode 241, emissive layers 242, and a cathode electrode 243 may be employed as an example of a light-emitting element.

The anode electrode 241 may be formed on the organic film 239. The anode electrode 241 may be connected to the source electrode 233 or the drain electrode 234 of the thin-film transistor 235 via a contact hole penetrating through the protective film 238 and the organic film 239.

The bank may be formed to cover an edge of the anode electrode 241 on the organic film 239 to define emission areas EA of the pixels. In other words, the bank may define the emission areas EA of the pixels. In each of the pixels, the anode electrode 241, the emissive layer 242, and the cathode electrode 243 are sequentially stacked on one another, so that holes from the anode electrode 241 and electrons from the cathode electrode 243 combine in the emissive layer 242 to emit light.

The emissive layers 242 are formed on the anode electrodes 241 and the bank. The emissive layers 242 may be organic emissive layers. The emissive layers 242 may emit one of a red light, a green light, or a blue light. As another example, the emissive layer 242 may be a white emissive layer that emits white light. In this case, a red emissive layer, a green emissive layer, and a blue emissive layer may be stacked on one another, or may be formed commonly across the pixels as a common layer. In this case, the display panel 200 may further include additional color filters for representing red, green, and blue colors.

The emissive layer 242 may include a hole transporting layer, a light-emitting layer, and an electron transporting layer. In addition, the emissive layer 242 may be formed in a tandem structure of two or more stacks, in which case a charge generating layer may be formed between the stacks.

The cathode electrode 243 is formed on the emissive layer 242. The cathode electrode 243 may be formed to cover the emissive layer 242. The cathode electrode 243 may be a common layer formed across the pixels.

When the light-emitting element layer 204 is of a top-emission kind in which light exits toward the upper side, the anode electrode 241 may be made of a metal material having a high reflectivity, such as a stack structure of aluminum and titanium (e.g., Ti/Al/Ti), a stack structure of aluminum and ITO (e.g., ITO/Al/ITO), an APC alloy, and/or a stack structure of an APC alloy and ITO (e.g., ITO/APC/ITO). The APC alloy is an alloy of silver (Ag), palladium (Pd), and copper (Cu). The cathode electrode 243 may be formed of a transparent conductive material (TCP), such as ITO and IZO, that may transmit light, or a semi-transmissive conductive material, such as magnesium (Mg), silver (Ag), and an alloy of magnesium (Mg) and silver (Ag). When the cathode electrode 243 is formed of a transluscent conductive material, the light extraction efficiency may be increased by using microcavities.

When the light-emitting element layer 204 is of a bottom-emission kind in which light exits toward the lower side, the anode electrode 241 may be formed of a transparent conductive material (TCP), such as ITO and IZO, that may transmit light, or a semi-transmissive conductive material, such as magnesium (Mg), silver (Ag), and an alloy of magnesium (Mg) and silver (Ag). The cathode electrode 243 may be made of a metal material having a high reflectivity, such as a stack structure of aluminum and titanium (e.g., Ti/Al/Ti), a stack structure of aluminum and ITO (e.g., ITO/Al/ITO), an APC alloy, and/or a stack structure of an APC alloy and ITO (e.g., ITO/APC/ITO). When the anode electrode 241 is formed of a semi-transmissive conductive material, the light extraction efficiency may be increased by using microcavities.

The encapsulation layer 205 is formed on the light-emitting element layer 204. The encapsulation layer 205 serves to prevent or substantially prevent permeation of oxygen or moisture into the emissive layers 242 and the cathode electrode 243. As such, the encapsulation layer 205 may include at least one inorganic film. The inorganic layer may be formed of silicon nitride, aluminum nitride, zirconium nitride, titanium nitride, hafnium nitride, tantalum nitride, silicon oxide, aluminum oxide, or titanium oxide. Further, the encapsulation layer 205 may further include at least one organic film. The organic film may have a sufficient thickness to prevent or substantially prevent particles from permeating into the encapsulation layer 205 and entering the emissive layer 242 and the cathode electrode 243. The organic layer may include one of an epoxy, acrylate, and/or urethane acrylate.

The sensor unit SENL may be formed on the encapsulation layer 205. When the sensor unit SENL is formed directly on the encapsulation layer 205, the thickness of the display device 10 may be reduced, compared with that of a display device in which a separate touch panel is attached on the encapsulation layer 205.

The sensor unit SENL may include sensor electrodes for sensing a user's touch by a capacitive sensing, and touch lines for connecting the pads with the sensor electrodes. For example, the sensor unit SENL may sense a user's touch by a self-capacitance sensing or a mutual capacitance sensing. In the example shown in FIG. 5, the sensor unit SENL is made up of two layers including driving electrodes TE, sensing electrodes RE, and bridges BE connecting between the driving electrodes TE for a mutual capacitance sensing.

The bridges BE may be formed on the encapsulation layer 205. The bridges BE may be made up of, but is not limited to, a stack structure of aluminum and titanium (e.g., Ti/Al/Ti), a stack structure of aluminum and ITO (e.g., ITO/Al/ITO), an APC alloy, and/or a stack structure of an APC alloy and ITO (e.g., ITO/APC/ITO). For example, the bridges BE may be made up of a single layer of molybdenum (Mo), titanium (Ti), copper (Cu), aluminum (Al), or ITO.

A first sensing insulating film TINS1 is formed over the bridges BE. The first sensing insulating film TINS1 may be formed of an inorganic film, for example, such as a silicon nitride layer, a silicon oxynitride layer, a silicon oxide layer, a titanium oxide layer, or an aluminum oxide layer.

The driving electrodes TE and the sensing electrodes RE may be formed on the first sensing insulating film TINS1. The driving electrode TE and the sensing electrode RE may be formed as, but is not limited to, a stack structure of aluminum and titanium (e.g., Ti/Al/Ti), a stack structure of aluminum and ITO (e.g., ITO/Al/ITO), an APC alloy, and/or a stack structure of an APC alloy and ITO (e.g., ITO/APC/ITO). For example, the driving electrodes TE and the sensing electrodes RE may be made up of a single layer of molybdenum (Mo), titanium (Ti), copper (Cu), aluminum (Al), or ITO.

Contact holes may be formed in the first sensing insulating film TINS1 to penetrate the first sensing insulating film TINS1 and to expose the bridges BE. The driving electrodes TE may be connected to the bridges BE through the contact holes.

A second sensing insulating film TINS2 is formed over the driving electrodes TE and the sensing electrodes RE. The second sensing insulating film TINS2 may provide a flat or substantially flat surface over the driving electrodes TE, the sensing electrodes RE, and the bridges BE, which have different heights. The second sensing insulating film TINS2 may be formed of an organic layer, such as an acryl resin, an epoxy resin, a phenolic resin, a polyamide resin, and/or a polyimide resin.

The bridges BE connecting between adjacent driving electrodes TE may be disposed on the encapsulation layer 205, and the driving electrodes TE and the sensing electrodes RE may be disposed on the first sensing insulating film TINS1. Therefore, the driving electrodes TE and the sensing electrodes RE may be electrically separated from each other at their intersections, while the sensing electrodes RE may be electrically connected with one another in a direction (e.g., in one direction), and the driving electrodes TE may be electrically connected with one another in another direction.

The polarizing film PF may be disposed on the second sensing insulating film TINS2, and may prevent or substantially prevent deterioration of an image visibility of the display panel 200 due to a reflection of external light.

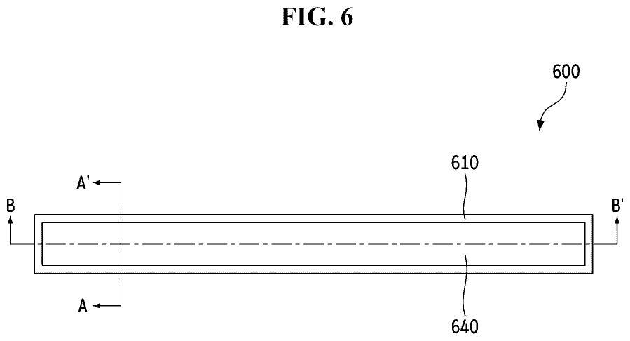

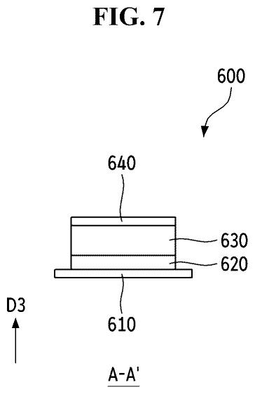

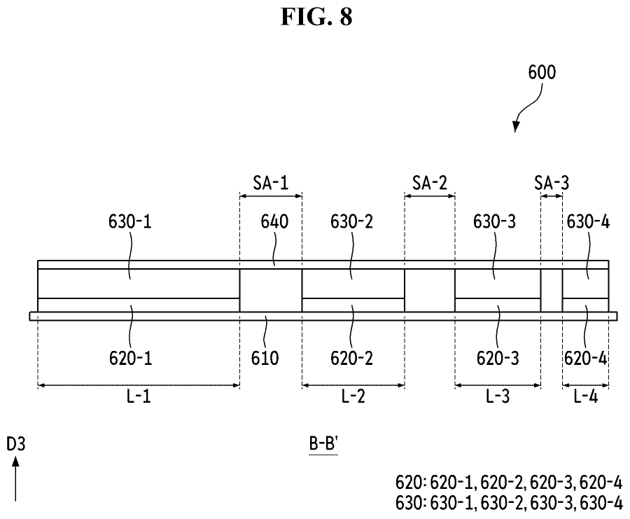

FIG. 6 is a plan view of the adhesive unit of FIG. 3. FIG. 7 is a cross-sectional view taken along the line A-A′ of FIG. 6. FIG. 8 is a cross-sectional view taken along the line B-B′ of FIG. 6. For example, FIG. 6 is a plan view of one of the adhesive units 600 shown in FIG. 3.

Referring to FIGS. 3 and 6 to 8, the adhesive unit 600 may couple the display device 10 with the bracket 22 (e.g., see FIG. 13). The adhesive unit 600 may be disposed on at least one of the cover window 100 or the panel bottom member 300. For example, there may be a plurality of adhesive units (e.g., a plurality of adhesive stacks) 600 on the cover window 100 and the panel bottom member 300.

As shown in FIG. 3, the adhesive units 600 disposed on the cover window 100 may be disposed on a portion of the cover window 100 where the cover window 100 and the panel bottom member 300 do not overlap with each other, and in a portion where the cover window 100 and the connecting member 400 do not overlap with each other. In some embodiments, the adhesive units 600 may be arranged along the edge of the cover window 100, and may be disposed at a portion of the edge of the cover window 100 where it does not overlap with the connecting member 400. The adhesive units 600 disposed on the cover window 100 may be in contact with the bracket 22. In some embodiments, the adhesive units 600 may be disposed between the cover window 100 and the bracket 22.

In addition, the adhesive units 600 disposed on the panel bottom member 300 may be disposed on the panel bottom member 300 where the panel bottom member 300 and the driver circuit board 500 do not overlap with each other. In some embodiments, a plurality of adhesive units 600 may be spaced apart from one another on the panel bottom member 300, and may be disposed in an area excluding the area where the panel bottom member 300 and the driver circuit board 500 overlap with each other. The adhesive units 600 disposed on the panel bottom member 300 may be in contact with the bracket 22. In some embodiments, the adhesive units 600 may be disposed between the panel bottom member 300 and the bracket 22.

An adhesive unit (e.g., an adhesive stack) 600 may include a first cover 610, a plurality of adhesive members, and a second cover 640. The plurality of adhesive members may include a plurality of first adhesive members 620, and a plurality of second adhesive members 630.

The first cover 610 may be provided as a sheet having a suitable thickness (e.g., a predetermined thickness). The shape of the first cover 610 when viewed from the top (e.g., in a plan view) may be a rectangular shape having a pair of longer sides extended in a direction (e.g., the right direction in FIG. 6), and a pair of shorter sides extended in another direction perpendicular to or substantially perpendicular to the direction. The first cover 610 may support the first adhesive members 620, the second adhesive members 630, and the second cover 640. The area of the first cover 610 may be larger than the area of the second cover 640 when viewed from the top (e.g., in a plan view). The first cover 610 may protect the first adhesive members 620 before the adhesive unit 600 is disposed on the cover window 100 or the panel bottom member 300. Therefore, when the adhesive unit 600 is disposed on the cover window 100 or the panel bottom member 300, the first cover 610 may be separated from the first adhesive members 620.

The first adhesive members 620 may be arranged to be spaced apart from one another in a direction (e.g., the right direction in FIG. 8) on the first cover 610. For example, the first adhesive members 620 may include a (1-1) adhesive member 620-1, a (1-2) adhesive member 620-2, a (1-3) adhesive member 620-3, and a (1-4) adhesive member 620-4. The (1-1) adhesive member 620-1, the (1-2) adhesive member 620-2, the (1-3) adhesive member 620-3, and the (1-4) adhesive member 620-4 may be spaced apart from one another in a direction (e.g., in one direction) on the first cover 610.

Lengths L-1, L-2, L-3, and L-4 of the first adhesive members 620 in a direction may gradually become shorter along the direction. For example, the length L-2 of the (1-2) adhesive member 620-2 in the direction may be shorter than the length L-1 of the (1-1) adhesive member 620-1 in the direction. The length L-3 of the (1-3) adhesive member 620-3 in the direction may be shorter than the length L-2 of the (1-2) adhesive member 620-2 in the direction. The length L-4 of the (1-4) adhesive member 620-4 in the direction may be shorter than the length L-3 of the (1-3) adhesive member 620-3 in the direction.

Because the first adhesive members 620 are spaced apart from each other in the direction, spaces may be formed between the first adhesive members 620. For example, a first space may be formed between the (1-1) adhesive member 620-1 and the (1-2) adhesive member 620-2, a second space may be formed between the (1-2) adhesive member 620-2 and the (1-3) adhesive member 620-3, and a third space may be formed between the (1-3) adhesive member 620-3 and the (1-4) adhesive member 620-4.

Lengths SA-1, SA-2, and SA-3 of the spaces in a direction may become shorter along the direction. For example, the length SA-2 of the second space in the direction may be shorter than the length SA-1 of the first space in the direction, and the length SA-3 of the third space in the direction may be shorter than the length SA-2 of the second space in the direction.

The second adhesive members 630 may be disposed on the first adhesive members 620 to come into contact with the bracket 22. The second adhesive members 630 may be arranged to be spaced apart from one another in a direction (e.g., the right direction in FIG. 8) on the first adhesive members 620. In some embodiments, the second adhesive members 630 may be disposed on the first adhesive members 620, and may be spaced apart from one another in the direction on the first adhesive members 620. For example, the second adhesive members 630 may include a (2-1) adhesive member 630-1, a (2-2) adhesive member 630-2, a (2-3) adhesive member 630-3, and a (2-4) adhesive member 630-4. The (2-1) adhesive member 630-1 may be disposed on the (1-1) adhesive member 620-1, the (2-2) adhesive member 630-2 may be disposed on the (1-2) adhesive member 620-2, the (2-3) adhesive member 630-3 may be disposed on the (1-3) adhesive member 620-3, and the (2-4) adhesive member 630-4 may be disposed on the (1-4) adhesive member 620-4.

Lengths L-1, L-2, L-3, and L-4 of the second adhesive members 630 in a direction may gradually become shorter in the direction. For example, the length L-2 of the (2-2) adhesive member 630-2 in the direction may be shorter than the length L-1 of the (2-1) adhesive member 630-1 in the direction. The length L-3 of the (2-3) adhesive member 630-3 in the direction may be shorter than the length L-2 of the (2-2) adhesive member 630-2 in the direction. The length L-4 of the (2-4) adhesive member 630-4 in the direction may be shorter than the length L-3 of the (2-3) adhesive member 630-3 in the direction.

The lengths L-1, L-2, L-3, and L-4 of the (2-1) adhesive member 630-1, the (2-2) adhesive member 630-2, the (2-3) adhesive member 630-3, and the (2-4) adhesive member 630-4 in the direction may be equal to or substantially equal to the lengths L-1, L-2, L-3, and L-4 of the (1-1) adhesive member 620-1, the (1-2) adhesive member 620-2, the (1-3) adhesive member 620-3, and the (1-4) adhesive member 620-4 in the direction.

The thickness of the second adhesive members 630 may be thicker than the thickness of the first adhesive members 620. For example, the thickness of the (2-1) adhesive member 630-1 may be thicker than the thickness of the (1-1) adhesive member 620-1, the thickness of the (2-2) adhesive member 630-2 may be thicker than the thickness of the (1-2) adhesive member 620-2, the thickness of the (2-3) adhesive member 630-3 may be thicker than the thickness of the (1-3) adhesive member 620-3, and the thickness of the (2-4) adhesive member 630-4 may be thicker than the thickness of the (1-4) adhesive member 620-4.

Because the second adhesive members 630 are spaced apart from each other in the direction, spaces may be formed between the second adhesive members 630. For example, a first space may be formed between the (2-1) adhesive member 630-1 and the (2-2) adhesive member 630-2, a second space may be formed between the (2-2) adhesive member 630-2 and the (2-3) adhesive member 630-3, and a third space may be formed between the (2-3) adhesive member 630-3 and the (2-4) adhesive member 630-4.

Lengths SA-1, SA-2, and SA-3 of the spaces in a direction may become shorter along the direction. For example, the length SA-2 of the second space in the direction may be shorter than the length SA-1 of the first space in the direction, and the length SA-3 of the third space in the direction may be shorter than the length SA-2 of the second space in the direction.

The second cover 640 may be provided as a sheet having a suitable thickness (e.g., a predetermined thickness). The shape of the second cover 640 when viewed from the top (e.g., in a plan view) may be a rectangular shape having a pair of longer sides extended in a direction (e.g., the right direction in FIG. 6), and a pair of shorter sides extended in another direction perpendicular to or substantially perpendicular to the direction. The second cover 640 may be disposed on the second adhesive members 630 to cover the second adhesive members 630. The area of the second cover 640 may be smaller than the area of the first cover 640 when viewed from the top (e.g., in a plan view). The second cover 640 may protect the second adhesive members 630 before the adhesive unit 600 comes into contact with the bracket 22. Therefore, when the adhesive unit 600 comes into contact with the bracket 22, the second cover 640 may be separated from the second adhesive members 630.

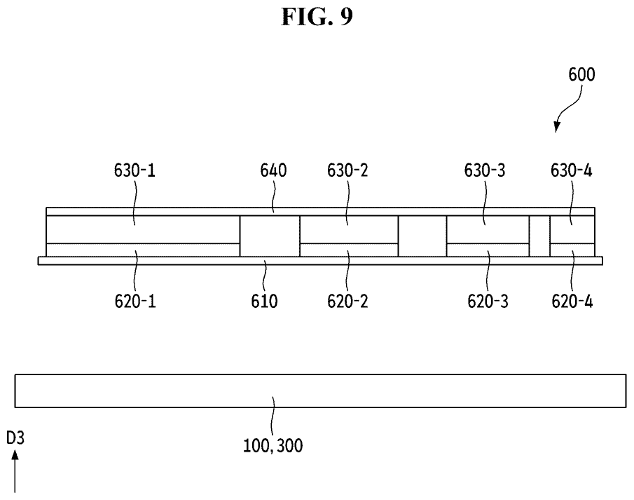

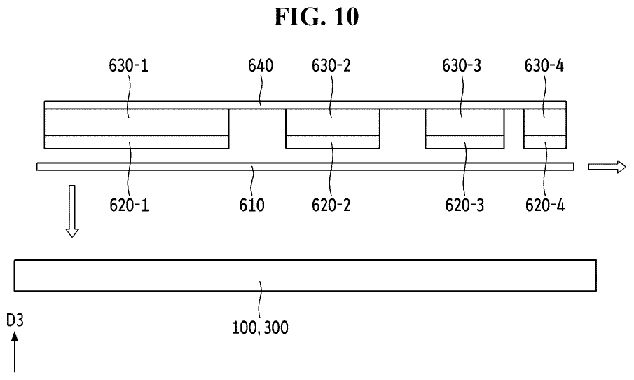

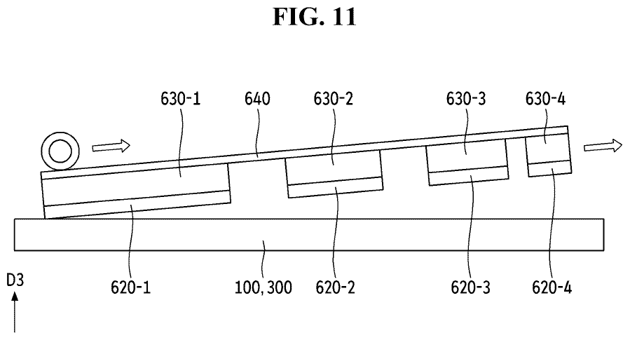

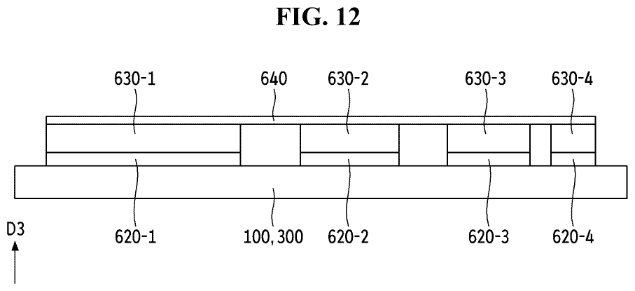

FIG. 9 is a view illustrating the adhesive unit of FIG. 3 disposed on the cover window or the panel bottom member. FIG. 10 is a view illustrating the first cover that is removed from the adhesive unit, and the adhesive unit is moved so that one side comes into contact with the cover window or the panel bottom member. FIG. 11 is a view illustrating a process of an adhesive roller that is moved while pressing the adhesive unit shown in FIG. 10. FIG. 12 is a view illustrating the adhesive unit that is attached to the cover window or the panel bottom member via the process shown in FIG. 11.

A process of attaching the adhesive unit 600 to the cover window 100 or the panel bottom member 300 will be described in more detail hereinafter with reference to FIGS. 9 to 12. As shown in FIG. 9, the adhesive unit 600 may be placed above the cover window 100 or the panel bottom member 300.

Once the adhesive unit 600 is placed above the cover window 100 or the panel bottom member 300, the first cover 610 may be separated from the first adhesive members 620, and then one side (e.g., the left side in FIG. 10) of the adhesive unit 600 in a direction may be moved downward, so that the one side of the adhesive unit 600 comes into contact with the cover window 100 or the panel bottom member 300, as shown in FIG. 11.

Once the one side of the adhesive unit 600 comes into contact with the cover window 100 or the panel bottom member 300, while the opposite side of the adhesive unit 600 in the direction may be pulled toward one side (e.g., the right side in FIG. 11), the adhesive unit 600 may be pressed downward toward the cover window 100 or the panel bottom member 300. The adhesive unit 600 may be pressed as a separate roller member moves from the one side to the opposite side of the adhesive unit 600 in a direction. As described above, by pressing the adhesive unit 600 by moving the roller member from one side to the opposite side of the adhesive unit 600 in the direction, the first adhesive members 620 may be attached to the cover window 100 or the panel bottom member 300, as shown in FIG. 12.

A plurality of adhesive members of the adhesive unit 600 may be arranged, such that they are spaced apart from one another in a direction. The lengths of the adhesive members in the direction may gradually become shorter along the direction, and the lengths of spaces formed between the adhesive members in the direction may also gradually become shorter along the direction, so that a deformation of the adhesive members may be reduced in the process of attaching the adhesive unit 600 while pulling the opposite side of the adhesive unit 600 in the direction. For example, in order to attach the adhesive unit 600 to the cover window 100 or the panel bottom member 300, the adhesive unit 600 may be attached while the (1-4) adhesive member 620-4 and the (2-4) adhesive member 630-4 are pulled. Because the lengths of the (1-4) adhesive member 620-4 and the (2-4) adhesive member (630-4) in a direction may be shorter than those of the other adhesive members, and the (1-4) adhesive member 620-4 and the (2-4) adhesive member 630-4 may be spaced apart from the other adhesive members, a deformation that may be caused by the (1-4) adhesive member 620-4 and the (2-4) adhesive member 630-4 being pulled in the direction may be reduced. Accordingly, the adhesive unit 600 may be attached to a desired position (e.g., a correct position) of the cover window 100 or the panel bottom member 300 by suppressing the deformation of the adhesive members.

FIG. 13 is a cross-sectional view illustrating an electronic device coupled with a display device according to an embodiment of the present disclosure.

Referring to FIG. 13, the back cover 20 may form a part of the exterior of the electronic device 1. The back cover 20 may be formed to surround (e.g., around a periphery of) the internal elements of the electronic device 1 except the cover window 100. In some embodiments, the back cover 20 may be disposed at the bottom of the display device 10 to cover the internal electronic components of the display device 10, thereby protecting the display device 10 from external impacts.

The vapor chamber 21 may be disposed on the back cover 20. The vapor chamber 21 may have a vacuum space formed therein, and a heat transfer medium may be accommodated in the internal vacuum space. The vapor chamber 21 may dissipate heat generated in the display device 10 by a phase change of the heat transfer medium accommodated in the internal vacuum space.

The bracket 22 may support the display device 10. The bracket 22 may be disposed under the panel bottom member 300, and may be disposed on the vapor chamber 21. In some embodiments, the bracket 22 may be disposed between the panel bottom member 300 and the vapor chamber 21.

The second adhesive members 630 of the adhesive unit 600 disposed on the panel bottom member 300 may come in contact with, and may be attached to, the bracket 22 disposed below (e.g., underneath) the panel bottom member 300. Before the second adhesive members 630 of the adhesive unit 600 disposed on the panel bottom member 300 come into contact with the bracket 22, the second cover 640 may be separated from the second adhesive members 630.

In addition, one end of the bracket 22 may protrude in the third direction D3, which is the thickness direction of the display device 10, and may be located under the cover window 100. The second adhesive members 630 of the adhesive unit 600 disposed on the cover window 100 may come in contact with, and may be attached to, the end of the bracket 22. Before the second adhesive members 630 of the adhesive unit 600 disposed on the cover window 100 come into contact with the end of the bracket 22, the second cover 640 may be separated from the second adhesive members 630.

As described above, as the cover window 100 and the panel bottom member 300 are attached to the bracket 22 by the adhesive unit 600, the display device 10 may be coupled with the bracket 22 of the electronic device 1.

The foregoing is illustrative of some embodiments of the present disclosure, and is not to be construed as limiting thereof. Although some embodiments have been described, those skilled in the art will readily appreciate that various modifications are possible in the embodiments without departing from the spirit and scope of the present disclosure. It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. Therefore, it is to be understood that the foregoing is illustrative of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

What is claimed is:

1. A display device comprising:
a cover window;
a display panel on the cover window;
a panel bottom member on the display panel; and
an adhesive unit on at least one of the cover window or the panel bottom member,
wherein the adhesive unit comprises a plurality of adhesive members spaced from one another in a direction to have spaces between the adhesive members.

2. The display device of claim 1, wherein lengths of the adhesive members in the direction become shorter along the direction.

3. The display device of claim 1, wherein lengths of the spaces in the direction become shorter along the direction.

4. The display device of claim 1, wherein the adhesive unit further comprises:
a first cover covering a surface of the adhesive members; and
a second cover covering an opposite surface of the adhesive members, and
wherein the first cover is configured to be separated from the adhesive members before the adhesive unit is disposed on at least one of the cover window or the panel bottom member.

5. The display device of claim 4, wherein an area of the first cover is larger than an area of the second cover in a plan view.

6. The display device of claim 1, wherein the adhesive members comprise:
a plurality of first adhesive members on at least one of the cover window or the panel bottom member; and
a plurality of second adhesive members on the first adhesive members.

7. The display device of claim 6, wherein lengths of the first and second adhesive members in the direction become shorter along the direction.

8. The display device of claim 6, wherein a thickness of the first adhesive members is smaller than a thickness of the second adhesive members.

9. The display device of claim 1, further comprising:
a connecting member connected to the display panel; and
a driver circuit board connected to the connecting member,
wherein the driver circuit board overlaps with a portion of the panel bottom member when the connecting member is bent, and
wherein the adhesive unit is located on a portion of the panel bottom member where the driver circuit board and the panel bottom member do not overlap with each other.

10. The display device of claim 9, wherein the adhesive unit is located on the cover window in an area where the cover window and the panel bottom member do not overlap with each other, and in an area where the cover window and the connecting member do not overlap with each other.

11. An electronic device comprising:
a cover window;
a display panel on the cover window;
a panel bottom member on the display panel;
a bracket supporting the cover window and the panel bottom member; and
a plurality of adhesive units between the cover window and the bracket, and between the panel bottom member and the bracket,
wherein each of the adhesive units comprises a plurality of adhesive members, and
wherein the adhesive members are spaced from one another in a direction to have spaces between the adhesive members.

12. The electronic device of claim 11, wherein lengths of the adhesive members in the direction become shorter along the direction.

13. The electronic device of claim 11, wherein lengths of the spaces in the direction become shorter along the direction.

14. The electronic device of claim 11, wherein each of the adhesive units further comprises:
a first cover covering a surface of the adhesive members; and
a second cover covering an opposite surface of the adhesive members,
wherein the first cover of a corresponding adhesive unit of the adhesive units is configured to be separated from the adhesive members before the corresponding adhesive unit comes into contact with the cover window or the panel bottom member, and
wherein the second cover of the corresponding adhesive unit is configured to be separated from the adhesive members before the corresponding adhesive unit comes into contact with the bracket.

15. The electronic device of claim 14, wherein an area of the first cover is larger than an area of the second cover in a plan view.

16. The electronic device of claim 11, wherein the adhesive members comprise:
a plurality of first adhesive members on the cover window or the panel bottom member; and
a plurality of second adhesive members on the bracket, and
wherein the first adhesive members and the second adhesive members overlap with each other.

17. The electronic device of claim 16, wherein lengths of the first and second adhesive members in the direction become shorter along the direction.

18. The electronic device of claim 16, wherein a thickness of the first adhesive members is smaller than a thickness of the second adhesive members.

19. The electronic device of claim 11, further comprising:
a connecting member connected to the display panel; and
a driver circuit board connected to the connecting member,
wherein the driver circuit board overlaps with a portion of the panel bottom member when the connecting member is bent, and
wherein at least one of the adhesive units is located on a portion of the panel bottom member where the driver circuit board and the panel bottom member do not overlap with each other.

20. The electronic device of claim 19, wherein at least some of the adhesive units are located on the cover window in an area where the cover window and the panel bottom member do not overlap each other, and in an area where the cover window and the connecting member do not overlap with each other.
